(19) United States
(12) Patent Application Publication
(10) Pub. No.: US 2008/0158819 A1
(43) Pub. Date: Jul. 3, 2008

(54) HEAT TRANSFER APPARATUS CONTAINING A COMPLIANT FLUID FILM INTERFACE AND METHOD THEREFOR

(75) Inventors: Vijayeshwar Das Khanna, Millwood, NY (US); Gerard McVicker, Stormville, NY (US); Sri M. Sri-Jayantha, Ossining, NY (US)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: International Business Machines Corporation, Armonk, NY (US)

(21) Appl. No.: 11/619,476

(22) Filed: Jan. 3, 2007

(51) Int. Cl. H05K 7/20

(52) U.S. Cl. 361/702

(57) ABSTRACT

A heat transfer device (and method therefore) for transferring heat from a heat source to a heat conductor, includes a fluid film operable as a compliant interface between the heat source and the heat conductor. The heat source includes a microelectronic device.

### BACKGROUND OF THE INVENTION

1. Field of the Invention

The present invention generally relates to a method and apparatus for cooling electronic components, and more particularly to a method and apparatus for heat transfer using a compliant fluid film interface.

2. Description of the Related Art

Present cooling devices are configured to make contact with a computer chip through a paste-like thermal interface material (TIM). The TIM generally has poor thermal conductivity.

Therefore, it is desirable to minimize the thickness of the TIM to keep the thermal resistance as low as possible. However, a finite (e.g., 100 μm) mechanical clearance is needed between the chip surface and a cooling device, to accommodate thermal expansion and contraction encountered during the power cycles of a system. A cooling device for a microprocessor may weigh as much as (>0.5 kg), and typically cannot be directly attached to a chip because the mechanical stresses may unfavorably strain and crack the chip.

Hence, there is a need to develop a cooling device which can remove heat from a silicon chip without demanding a large gap or straining the chip in the process.

### SUMMARY OF THE INVENTION

In view of the foregoing and other exemplary problems, drawbacks, and disadvantages of the conventional methods and structures, an exemplary feature of the present invention is to provide a method and structure in which a fluid film provides a compliant interface.

In a first exemplary aspect of the present invention, a heat transfer device for transferring heat from a heat source to a heat conductor, includes a fluid film operable as a compliant interface between the heat source and the heat conductor. The heat source includes a microelectronic device.

In a second exemplary aspect of the present invention, a method for transferring heat from a heat source to a heat conductor, includes providing a fluid film operable as a compliant interface between the heat source and the heat conductor. The heat source includes a microelectronic device.

In a third exemplary aspect of the present invention, a heat transfer device, includes a fluid film providing a compliant interface between a heat source and a heat conductor, the fluid adjusting and controlling a gap between the heat source and the heat conductor

The use of a fluid film as an intermediate layer for linking a kinetic (moving) heat sink and a stationary heat source has been disclosed (e.g., U.S. Patent Application No. 2005/0083655A1 Dielectric Thermal Stack for the Cooling of High Power Electronics” to Zairazbhoy et al.). The fluid film provides a medium for convective heat transfer of heat flux conducted thereto through a thin metal separator. The presence of a fluid film fortunately lends itself to consider a compliant intermediate interface. Because of vigorous circulation of fluid film with the volume provided for it, micrometer level variation (e.g., 10 μm) in fluid film thickness does not cause variation in heat dissipating ability.

Therefore, by designing the metallic separator that isolates the fluid film from the heat source with compliance along its periphery, the needed space for thermal expansion mismatch is provided. Existence of compliance further allows minimum gap TIM as well as eliminates a paste depletion (or pumping) problem.

### BRIEF DESCRIPTION OF THE DRAWINGS

The foregoing and other exemplary purposes, aspects and advantages will be better understood from the following detailed description of an exemplary embodiment of the invention with reference to the drawings, in which:

FIGS. 1(a)-1(b) illustrate a conventional heat sink and a kinetic heat sink (KHS), respectively;

FIG. 2 illustrates a conventional KHS with a fixed shaft;

FIG. 3 illustrates a conventional KHS with a moving shaft;

FIGS. 4(a)-4(c) illustrate a compliant interface on a conventional KHS according to an exemplary embodiment of the present invention;

FIGS. 5(a)-5(c) illustrates a compliant interface with a rotating shaft 502 supported by horizontal ribs 502A;

FIG. 6 illustrates an exploded view of the structure of FIGS. 5(a)-5(c);

FIG. 7 illustrates a full isometric view of the structure of FIGS. 5(a)-5(c);

FIGS. 8(a)-8(b) illustrate an enhanced heat transfer surface formed of concentric rings of a fluid film; and

FIG. 9 illustrates pressure exerting tabs.

### DETAILED DESCRIPTION OF EXEMPLARY EMBODIMENTS OF THE INVENTION

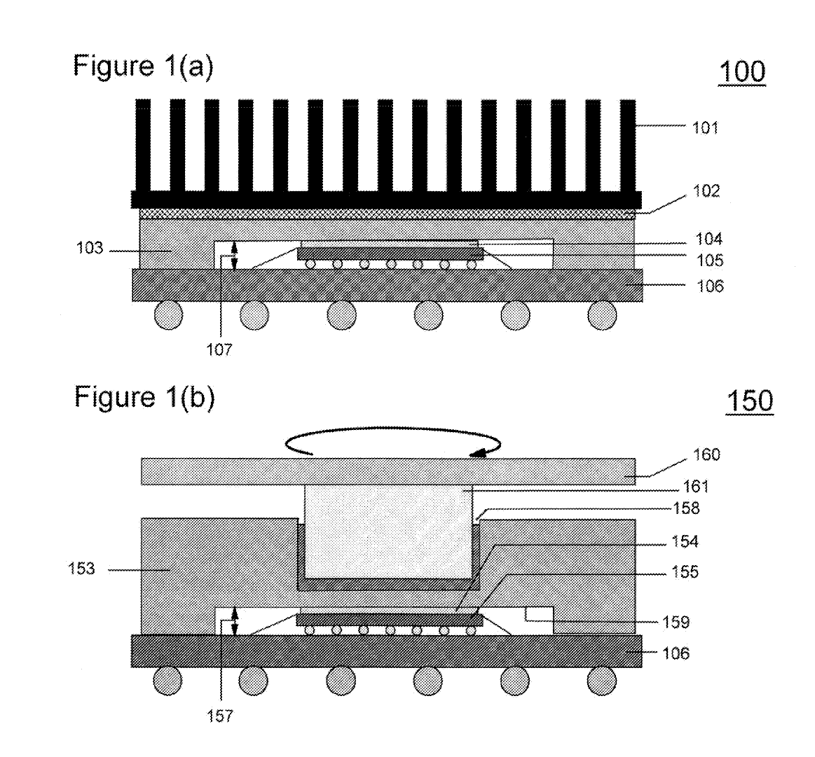

Referring now to the drawings, and more particularly to FIGS. 1(a)-9, there are shown exemplary embodiments of the method and structures according to the present invention.

### Exemplary Embodiment

FIG. 1(a) shows a conventional structure 100 including a static heat sink 101. A thermal interface material (TIM) 102 provides heat conduction from one modular component to another, while absorbing the thermally induced variation in clearances between the components. A rigid heat spreader 103 is provided between TIM 102 and another TIM 104. TIM 104 is applied to a top surface of a die (chip) 105. “Legs” of the spreader 103 are mounted on a ceramic base 106. As shown by reference numeral 107, there is a rigid spacing between the under surface of the spreader 103 and a top surface of the ceramic base 106.

FIG. 1(b) shows a structure 150 including a novel kinetic heat sink (KHS) where a rigid heat spreader 153 supports a fluid film 158 on one side and provides a conduction path from a chip 155 to itself through a TIM 154. Also shown is a rigid metallic interface 159 (formed by the underside of the heat spreader 153).

As shown by reference numeral 157, there is a rigid spacing between the under surface of the spreader 153 and a top surface of the ceramic base 106. A metallic blade 160 is mounted above the heat spreader by way of a rotating shaft 161. The fluid film is positioned between the rotating shaft 161 and a cavity formed in the heat spreader 153. Thus, a kinetic heat sink is provided with a fluid dynamic bearing.

However, this conventional system does not envisage using the fluid film 158 as an asset for solving the thermally induced “gap” variation problem. Indeed, in the structure of FIG. 1(b), the TIM may not be trapped between the two parallel surfaces shown, and thus the conduction path will not be directly to the heat spreader 153. Further, the TIM 154 may flow out (escape) with expansion of the chip (by its own weight, etc.) and the spreader undesirably may move around, the TIM may squeeze out of the gap, thereby degrading the conduction path and creating air pockets or the like.

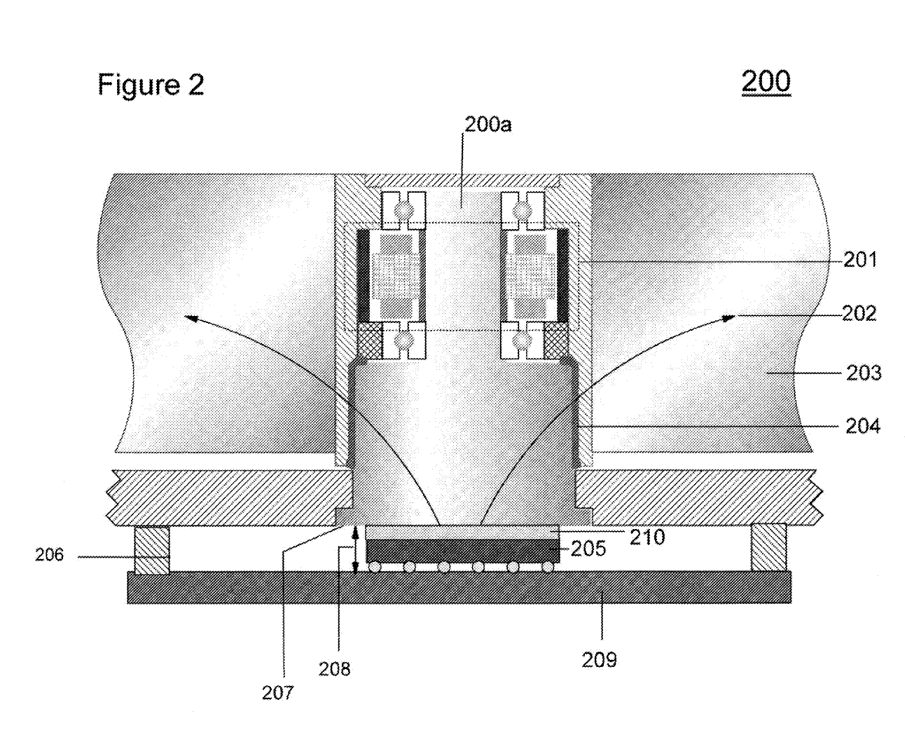

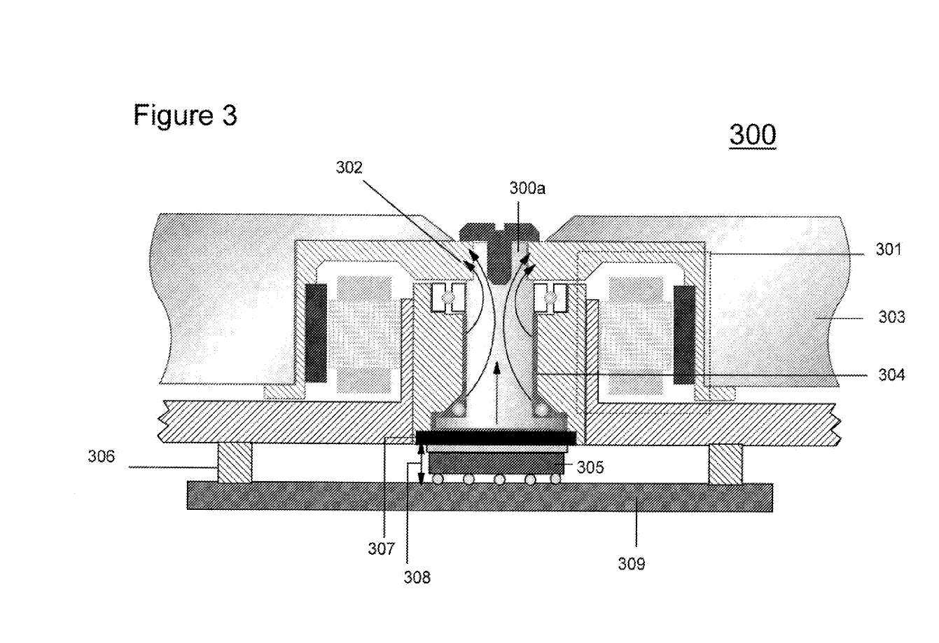

FIGS. 2 and 3 show variations in the conventional system corresponding to FIG. 1(b).

A structure 200 of FIG. 2 shows a kinetic heat sink with a fixed center shaft 200a (and fixed bearings etc.) and the fan blades rotate. Specifically, structure 200 includes a kinetic heat sink (KHS) including a motor 201, a thermal path 202, a fan blade 203, a fluid film 204, a chip 205, a supporting spacer 206, and a rigid metallic interface 207 separating the fluid film 204.

As shown by reference numeral 208, there is a rigid spacing between the under surface of the interface 207 and a top surface of a ceramic base 209.

A structure 300 of FIG. 3 shows a kinetic heat sink with a rotating center shaft 300a. Specifically, structure 300 includes a kinetic heat sink (KHS) including a motor 301, a thermal path 302, a fan blade 303, a fluid film 304, a chip 305, a supporting spacer 306, and a rigid metallic interface 307 separating the fluid.

As shown by reference numeral 308, there is a rigid spacing between the under surface of the interface 307 and a top surface of a ceramic base 309.

In each configuration, the method of supporting the rotational blade is varied. In FIG. 2, a fixed shaft 200a is employed. The heat flux from a source (chip) is conducted through a TIM 210 to the stationary shaft 200a. The shaft diameter is optimized for maximum surface area for heat conduction while providing a means for supporting the rotating components. It is noted that the base of the shaft that is in contact with the TIM 210 has a rigid interface, and hence a rigid spacing 208.

In FIG. 3, a rotating shaft 300a is employed. Again, the metallic interface 307 is treated as a rigid component.

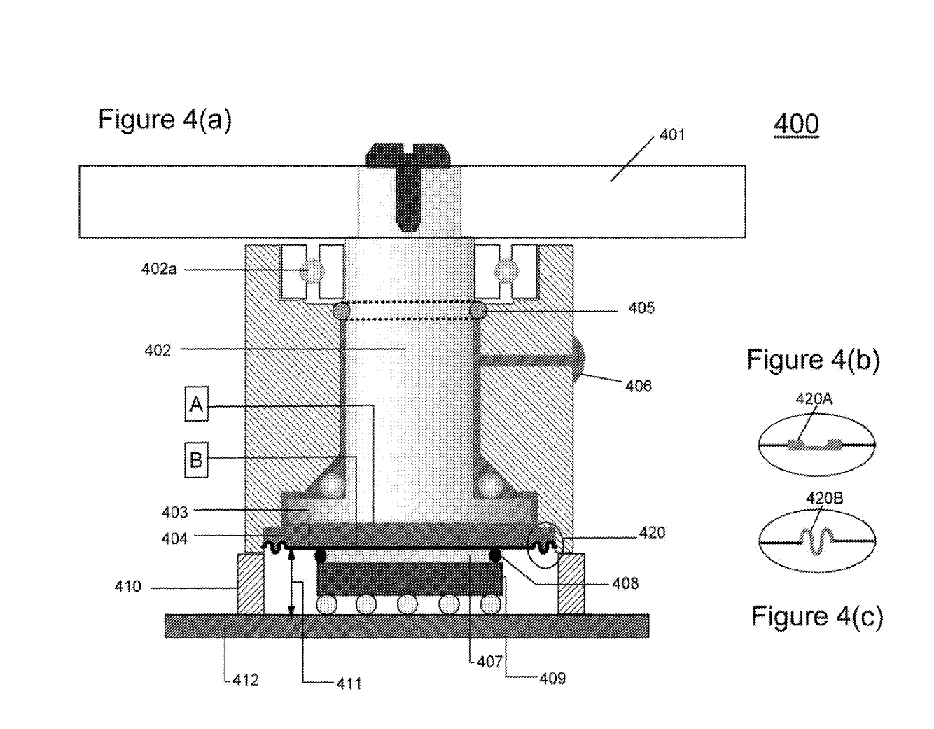

Turning now to FIGS. 4a-4c, an exemplary embodiment of the present invention will be described.

FIG. 4a illustrates a structure 400 showing the principle of a compliant interface containing a fluid film 404 in which a metallic blade 401 is rotated by a rotating shaft 402. The rotating shaft 402 configuration is readily adaptable to illustrate the present invention. A separator, or interface plate 403, as shown in FIG. 4a, is made compliant along the axis of rotation of the KHS by a compliant link 420 (which can be a viscoelastic link 420A or flexured link 420B, as shown in FIGS. 4b and 4c). It is noted that both types of links could be used together.

The fluid film 404 circulates due to rotation of the shaft 402 convecting the heat flux. The thickness of the film contained in between the shaft face A and separator surface B is made compliant by allowing the fluid to flow in and out of a flexible reservoir 406 whenever a displacement of the separator 403 is required. Thus, a flexible storage volume is provided. The fluid contained in the KHS is sealed using a field-proven system such as a labyrinth seal employing a fluid seal 405, etc.

It is noted that the shaft 402 that passes through the bearing 402a is thermally optimum when its diameter is made as large as possible.

Since the separator 403 is compliant, a conventionally-used large gap (about 100 μm) for the TIM 407 is no longer necessary. Only a guaranteed minimum space is needed to merge the two imperfect surfaces of the heat source and the separator's external surface. The minimum gap can be kept constant by, for example, a three-point spacer called a fixed gap spacer (FGS) 408.

A three-point design facilitates a planar contact on the chip surface. The fixed gap spacer 408 interacts with the compliant interface 403 as thermal expansion and contraction cycles occur while maintaining a fixed gap. Therefore, the traditional depletion of thermal paste is minimized, if not eliminated completely.

The three-point FGS can be modified to achieve other functions. For example, it can be a rectangular ridge and it would contain the TIM 407 by sealing the edge of the chip 409 (which also has the rectangular geometry).

Since the compliant interface 403 does not constrain the thermally induced relative motion, it can be permanently attached to the chip surface without any stress-related concern.

Many attachment technologies which could not be used prior to the present invention can now be considered. Use of thermal epoxies or eutectic solder are two candidates. The separator 403 can be made of silicon itself, thereby removing the in-plane thermal mismatch. On the other hand, any compatible metal with an extremely thin cross-section can also be considered for reducing in-plane stress due to thermal mismatch.

As further shown, a supporting spacer 410 is shown. Also shown is the feature of a variable gap surface 411 providing between the upper surface of the ceramic base 412 and the lower surface of the compliant link 420.

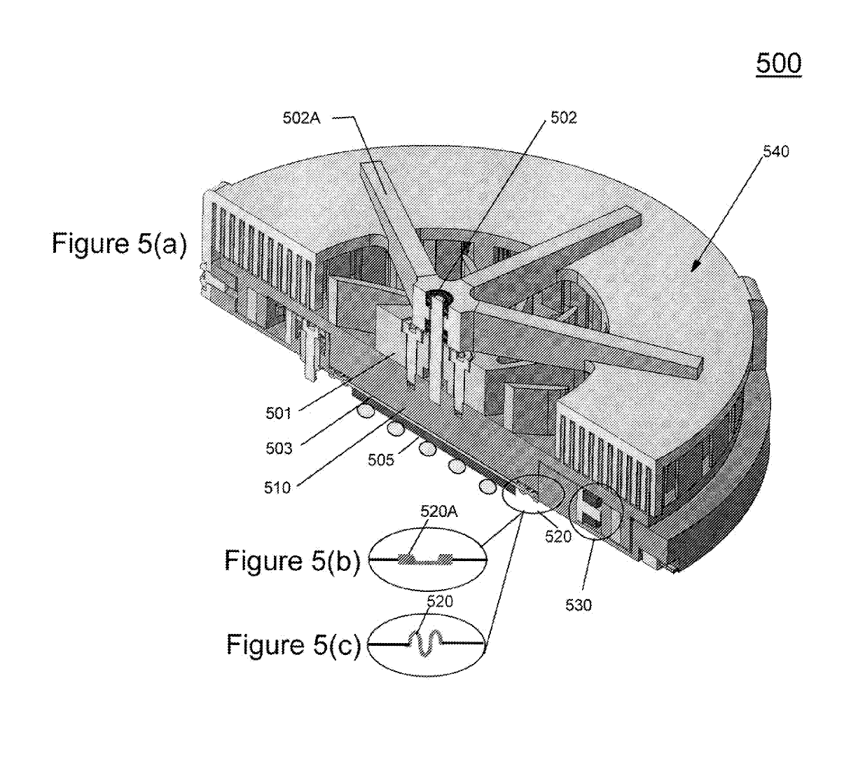

FIGS. 5(a)-5(c) show a sectional isometric view of an assembled KHS 500. In this embodiment, a blade 501 is mounted on rotating shaft 502 which is supported from the top by a plurality of ribs 502A. This exemplary embodiment allows the rotating fin assembly 510 to have a large wheel base. FIG. 5a further illustrates rotating fin assembly 510 A compliant link 520 is shown (and further shown in FIGS. 5b and 5c) as a viscoelastic link 520A or a flexured link 520B. As shown, the metallic blade 501 is rotated by a rotating shaft 502. A separator, or interface plate 503, as shown in FIG. 5a, is made compliant along the axis of rotation of the KHS by a complaint link 520 (which can be the viscoelastic link 520A or flexured link 520B, as shown in FIGS. 5b and 5c). The magnetics 530 for the torque generation is also shown as is chip 505 and a stationary air baffle 540.

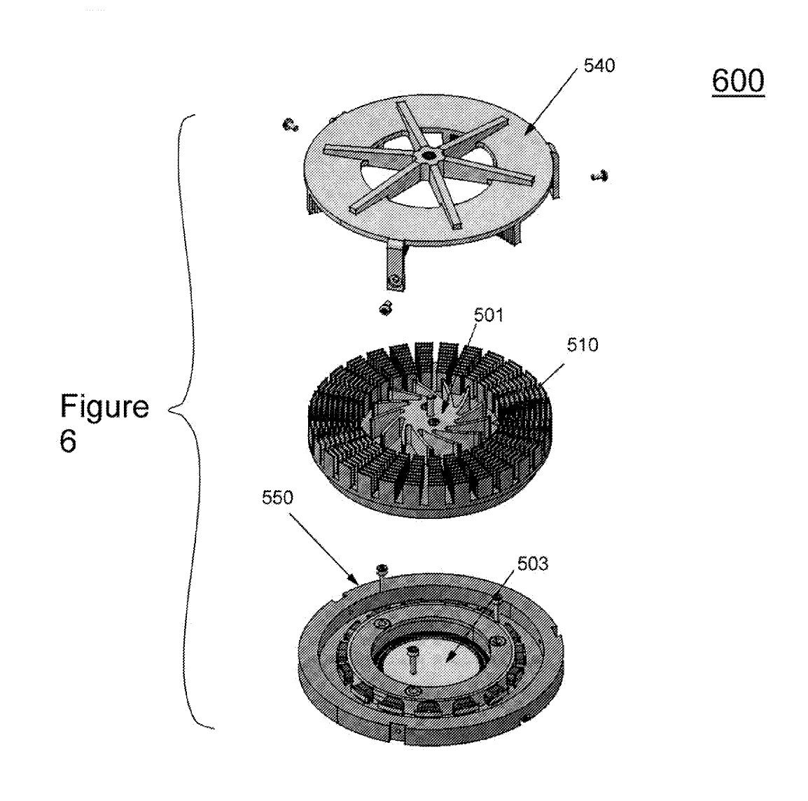

FIG. 6 is an exploded view of the embodiment of FIGS. 5(a)-5(c). As shown, the upper portion of FIG. 6 shows the baffle assembly 540, the middle portion shows the fan blade 501 and the fin assembly 510, whereas the lower portion of FIG. 6 shows the compliant interface plate 503 and the base assembly 550.

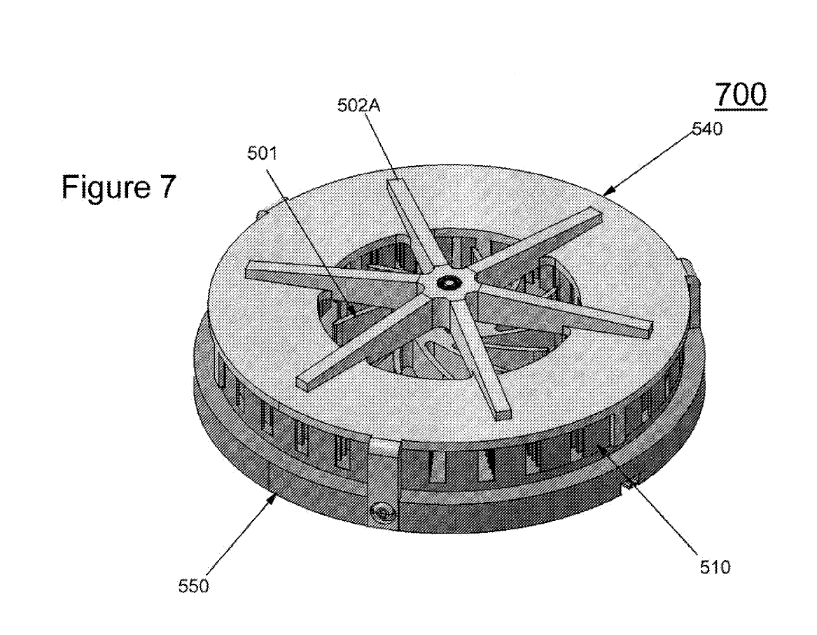

FIG. 7 is an assembled isometric view of the embodiment of FIGS. 5(a)-5(c), showing the fan blade 501, ribs 502A for the center shaft support, the air baffle 540, as well as the fin assembly 510 and base assembly 550.

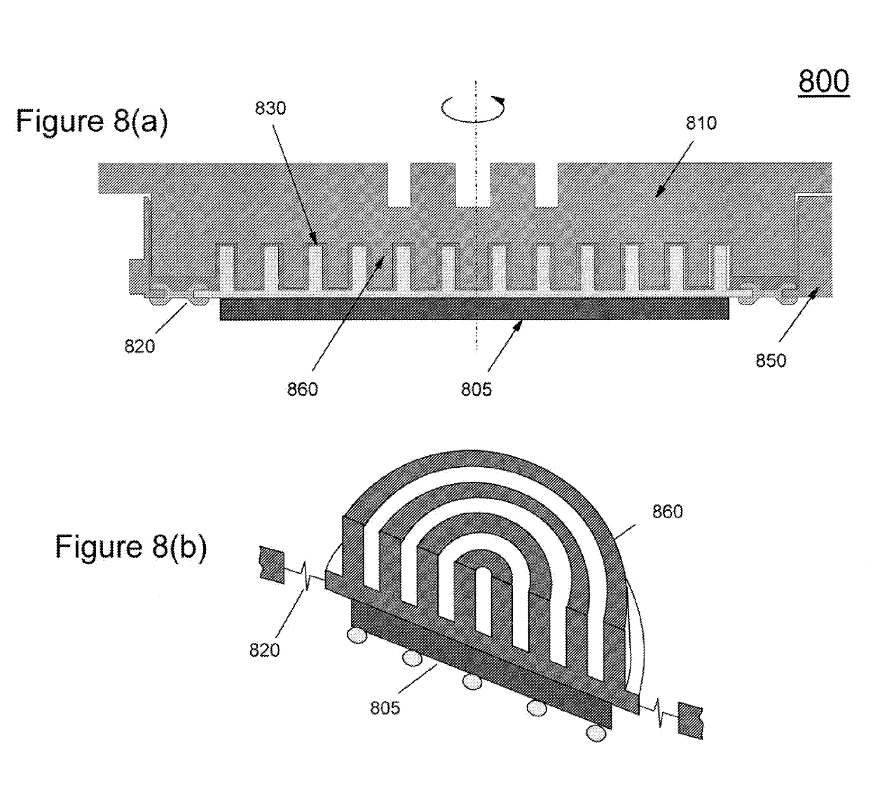

FIG. 8(a) shows a kinetic heat spreader (KHS) 800 with an enhanced surface area for heat transfer. That is, FIG. 8(a) shows a method where the surface area between the rotating part and the stationary separator is enhanced by, for example, multiple concentric circles of fluid channels.

In FIG. 8(a), a heat source (chip) 805 is shown as well as a fin assembly 810 for dissipating heat. Compliant link 820 is positioned above chip 805. An oil interface 830, which serves as the fluid film, is shown as well as base assembly 850 and concentric circular rings 860 to increase heat transfer area. FIG. 8(b) shows a sectional view of the concentric rings 860.

The fluid flow through the ring structure 860 may be integrated with a “pump” device.

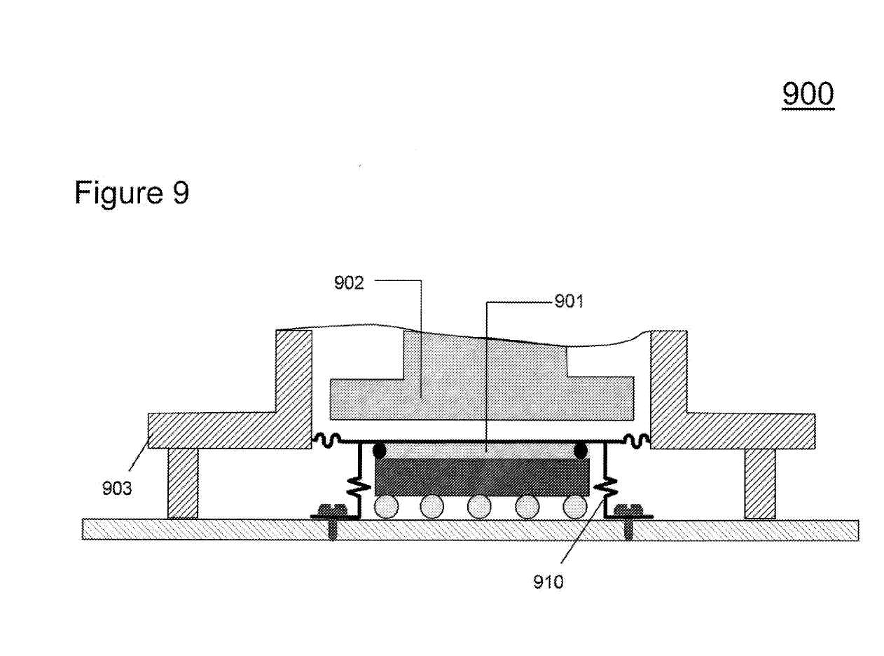

Some class of TIM material may require substantial pressure during the assembly process to help spread the high viscous paste in between the surfaces. In order to exert this pressure, the separator plate can be modified as shown in the structure 900 of FIG. 9.

That is, two or more tabs 910 extend from the separator (unreferenced) through which the normal pressure is exerted without straining the compliant periphery of the same plate. Also shown is TIM 901, center shaft 902, and printed circuit board 903.

Thus, the invention provides a fluid film as an intermediate layer for linking a kinetic (moving) heat sink and uses a metallic separator that isolates the fluid film from the heat source with compliance along its periphery, such that the needed space for thermal expansion mismatch is provided. Additionally, the inventors have recognized that the compliance further allows a minimum gap TIM as well as eliminates a paste depletion (or pumping) problem.

While the invention has been described in terms of several exemplary embodiments, those skilled in the art will recognize that the invention can be practiced with modification within the spirit and scope of the appended claims.

Further, it is noted that Applicant's intent is to encompass equivalents of all claim elements, even if amended later during prosecution.

What is claimed is:

1. A heat transfer device for transferring heat from a heat source to a heat conductor, said heat transfer device comprising:
a fluid film operable as a compliant interface between said heat source and said heat conductor, said heat source comprising a microelectronic device.

2. The heat transfer device of claim 1, further comprising:
a fluid reservoir that allows a volume change associated with compliant motion of the compliant interface.

3. The heat transfer device of claim 1, further comprising:
a thermal interface material (TIM); and
a three-point separator that maintains a constant gap volume for said thermal interface material.

4. The heat transfer device of claim 3, further comprising:
a rectangular ridge for a fixed gap spacer (FGS) that contains the TIM while maintaining a constant gap.

5. The heat transfer device of claim 1, further comprising:
a compliant separator that is directly attached to a heat source by one of thermal epoxy and a solder interface.

6. The heat transfer device of claim 1, further comprising:
a plurality of concentric rings that enhance a heat transfer surface.

7. The heat transfer device of claim 5, further comprising:
a thermal interface material (TIM); and
means for exerting pressure on the separator during assembly with a certain class of said TIM.

8. A method for transferring heat from a heat source to a heat conductor, said method comprising:
providing a fluid film operable as a compliant interface between said heat source and said heat conductor, said heat source comprising a microelectronic device.

9. The heat transfer method of claim 8, further comprising:
providing a fluid reservoir that allows a volume change associated with compliant motion of the compliant interface.

10. The heat transfer method of claim 9, further comprising:
providing a thermal interface material; and
maintaining, via a three-point separator, a constant gap volume for said thermal interface material (TIM).

11. The heat transfer method of claim 10, further comprising:
containing the TIM with a rectangular ridge for a fixed gap spacer (FGS) while maintaining a constant gap.

12. The heat transfer method of claim 8, further comprising:
directly attaching a compliant separator to a heat source by one of thermal epoxy and a solder interface.

13. The heat transfer method of claim 8, further comprising:
enhancing a heat transfer surface with a plurality of concentric rings.

14. The heat transfer method of claim 13, further comprising:
providing a thermal interface material (TIM); and
exerting pressure on the separator during assembly with a certain class of said TIM.

15. The heat transfer device of claim 5, wherein said compliant separator comprises a viscoelastic link.

16. The heat transfer device of claim 5, wherein said compliant separator comprises a flexured link.

17. A heat transfer device, comprising:
a fluid film providing a compliant interface between a heat source and a heat conductor, the fluid adjusting and controlling a gap between said heat source and said heat conductor.

18. The heat transfer device of claim 17, further comprising:
a fluid reservoir that allows a volume change associated with compliant motion of the compliant interface.

19. The heat transfer device of claim 17, further comprising:
a thermal interface material; and
a three-point separator that maintains a constant gap volume for said thermal interface material (TIM).

20. The heat transfer device of claim 17, further comprising:
a compliant separator that is directly attached to the heat source by one of thermal epoxy and a solder interface.
